(19) United States
(12) Patent Application Publication
(10) Pub. No.: US 2007/0001100 A1
(43) Pub. Date: Jan. 4, 2007

(54) LIGHT REFLECTION FOR BACKSIDE ILLUMINATED SENSOR

(75) Inventors: Tzu-Hsuan HSU, Kaohsiung City (TW); Shou-Gwo WUU, Hsin-Chu City (TW); Dun-Nian YAUNG, Taipei City (TW)

Correspondence Address: HAYNES AND BOONE, LLP, 901 MAIN STREET, SUITE 3100, DALLAS, TX, 75202, US

(73) Assignee: TAIWAN SEMICONDUCTOR MANUFACTURING COMPANY, LTD., Hsin-Chu (TW)

(21) Appl. No.: 11/424,286

(22) Filed: Jun. 15, 2006

Related U.S. Application Data
(60) Provisional application No. 60/695,682, filed on Jun. 30, 2005.

(51) Int. Cl. H01L 31/00

(52) U.S. Cl. 250/214.1

(57) ABSTRACT

The present disclosure provides a backside illuminated semiconductor device. The device includes a semiconductor substrate having a front surface and a back surface, a sensor element formed on the front surface of the semiconductor substrate, and a light reflective layer (LRL) disposed over the sensor element. The LRL is configured to reflect light directed towards the back surface and through the sensor element.

This patent claims the benefit of U.S. Provisional Ser. No. 60/695,682 filed Jun. 30, 2005, the disclosure of which is hereby incorporated by reference.

### BACKGROUND

In semiconductor technologies, backside-illuminated sensors are used for sensing a volume of exposed light projected towards the backside surface of a substrate. The backside-illuminated sensors can be formed on the front side of the substrate, which has to be thin enough so that light projected towards the backside of the substrate can reach the sensors. However, a thin substrate will degrade the sensitivity of the sensors. For example, a long wavelength light may shine through the sensors without efficient absorption. Improvements in backside illuminated sensors and/or the corresponding substrate are desired.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIGS. 1 through 3 illustrate sectional views of various embodiments of a semiconductor device having a plurality of backside illuminated sensors constructed according to aspects of the present disclosure.

### DETAILED DESCRIPTION

It is to be understood that the following disclosure provides many different embodiments, or examples, for implementing different features of various embodiments. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact.

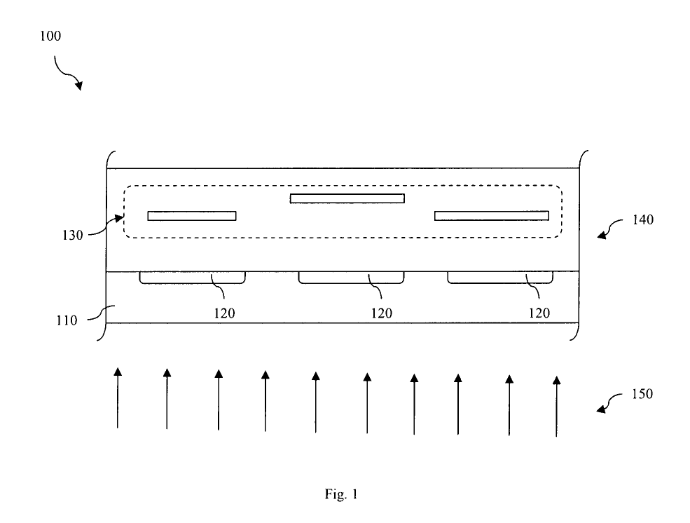

FIG. 1 illustrates a sectional view of one embodiment of a semiconductor device 100 having a plurality of backside illuminated (or back-illuminated) sensors constructed according to aspects of the present disclosure.

The semiconductor device 100 includes a semiconductor substrate 110. The substrate 110 may comprise an elementary semiconductor such as silicon, germanium, and diamond. The substrate 110 may also comprise a compound semiconductor such as silicon carbide, gallium arsenic, indium arsenide, and indium phosphide. The substrate 110 may comprise an alloy semiconductor such as silicon germanium, silicon germanium carbide, gallium arsenic phosphide, and gallium indium phosphide. The substrate 110 may comprise various p-type doped regions and/or n-type doped regions. All doping may be implemented using a process such as ion implantation or diffusion in various steps. The substrate 110 may comprise lateral isolation features to separate different devices formed on the substrate.

The semiconductor device 100 may include a plurality of sensor elements 120 formed on the front surface of the semiconductor substrate 110. In one embodiment, the sensor elements may be disposed over the front surface and extended into the semiconductor substrate 110. The sensor elements 120 each may comprise a light-sensing region (or photo-sensing region) which may be a doped region having N-type and/or P-type dopants formed in the semiconductor substrate 110 by a method such as diffusion or ion implantation. The light-sensing region may have a doping concentration ranging between about 10¹⁴ and 10²¹ atoms/cm³. The light-sensing region may have a surface area ranging between about 10% and 80% of the area of the associated sensor element, being operable to receive light illuminated thereon. The sensor elements 120 may include photodiodes, complimentary metal-oxide-semiconductor (CMOS) image sensors, charged coupling device (CCD) sensors, active pixel sensor, passive pixel sensor, and/or other sensors diffused or otherwise formed in the substrate 110. As such, the sensor elements 120 may comprise conventional and/or future-developed image sensing devices. The sensor elements 120 may comprise a plurality of pixels disposed in a sensor array or other proper configuration. The plurality of sensor pixels may be designed having various sensor types. For example, one group of sensor pixels are CMOS image sensors and another group of sensor pixels are passive sensors. Moreover, the sensor elements 120 may comprise color image sensors and/or monochromatic image sensors. The sensor elements 120 may further comprise or be coupled to components such as an electric circuit and connection such that the sensor elements 120 are operable to provide a proper response to illuminated light. The device 100 is designed to receive light 150 directed towards the back surface of the semiconductor substrate 110 during applications, eliminating other objects such as gate features and metal lines from obstructing the optical paths, and maximizing the exposure of the light-sensing region to the illuminated light. The substrate 110 may be thinned such that the light directed through the back surface thereof may effectively reach the sensor elements 120.

The semiconductor device 100 further comprises a light reflective layer (LRL) 130 formed on the front surface of the semiconductor substrate 110. The LRL 130 may be disposed over the sensor elements 120 formed on the semiconductor substrate 110 such that the light directed towards the back surface of the substrate 110 and through the sensor elements 120 can be reflected back to the sensor elements 120, the sensitivity thereof is thus enhanced. The LRL 130 may be designed and configured such that the backside illuminated light can be effectively reflected onto light-sensing regions. In one example, more than 80% of backside-illuminated light directed through a light-sensing region may be reflected back. In one example, the LRL 130 may have a reflectivity substantially at least 30% to the backside illuminated light. The LRL 130 may have a reflective surface to an associated sensor element in which the reflective surface has a surface area substantially at least 80% that of the associated sensor element. The LRL 130 may have a thickness ranging between about 50 angstroms and 20 micrometers. The LRL may be designed closer to the sensor elements 120 for maximized efficiency and performance. In one embodiment, the LRL 130 is formed in metal interconnect and/or interlayer dielectric (ILD). The LRL 130 may be designed to have a continuous reflective surface to reflect the backside illuminated light to the plurality of sensor elements 120. Alternatively, the LRL 130 may comprise a plurality of reflective separated/connected features patterned and disposed in the same layer or scattered in various layers. For example, a portion of the LRL 130 may be disposed in Metal 1 layer and another portion thereof may be disposed in Metal 2 layer. In another example, the reflective surface associated to one light-sensing region may comprise more than one reflective features. The LRL 130 may comprise functional components of the device 100 such as contacts, vias, and metal lines. These functional features may be configured for more effective light reflection, in addition to its normal functions. For example, a metal line strip may be relocated and/or widened without changing its normal functions. The LRL 130 may include metal, dielectric, other process/manufacturing compatible materials, and/or combinations thereof. The metal in LRL 130 may include aluminum, copper, tungsten, titanium, titanium nitride, tantalum, tantalum nitride, metal silicide, or combinations thereof. The dielectric in LRL 130 may include silicon oxide, silicon nitride, silicon oxynitride, low k material, or combinations thereof. In one embodiment, the dielectric in LRL 130 has an extinction coefficient less than about 2. In another example, the LRL 130 may be designed to include reflective features having a curved surface for focused and efficient reflection. The LRL 130 may comprise reflective features having a stacked multi-films structure such as a sandwiched structure having one film of a first type interposed between two films of a second type.

The device 100 may comprise multilayer interconnect (MLI) 140 formed on the semiconductor substrate 110 and over the sensor elements 120. The MLI 140 may be disposed and formed along with the LRL 130. The device 100 may include a passivation layer disposed over the MLI 140. The device 100 may further comprise a transparent layer attached to the back surface of the semiconductor substrate 110 to mechanically support thereof and optically allow the backside-illuminated light passing through. The device 100 may further comprise color filters interposed between the sensor elements 120 and the back surface of the semiconductor substrate 110 for color imaging applications. The device 100 may comprise a plurality of micro-lens interposed between the sensor elements 120 and the back surface of the semiconductor substrate 110, or between the color filters and the back surface if the color filters are implemented, such that the backside-illuminated light can be focused on the light-sensing regions. The LRL 130 may have enhanced reflectivity by utilizing a material having a higher reflectivity and/or adopting a stacked multi-film structure. The stacked multi-film structure may be designed such that thickness and reflective index of each layer are well tuned to enhance the reflectivity. For example, the thicknesses of the multiple films may be tuned such that the light reflected from various films will constructively interfere and the reflected light is thus reinforced. The reflective index of each layer may be carefully chosen or tuned such that the reflection from the stacked multi-films structure is maximized. The LRL 130 may be formed by various processes compatible and integral to the conventional processing technologies such as dual damascene processing. The method to form the LRL 130 may utilize deposition techniques such as chemical vapor deposition (CVD), physical vapor deposition (PVD), atomic layer deposition (ALD), plating, spin-on coating, and other suitable process. The method may further implement other processes such as polishing/planarization, etching, photolithography, and thermal process. Processing recipes may be optimized for expected refractive index and/or thickness.

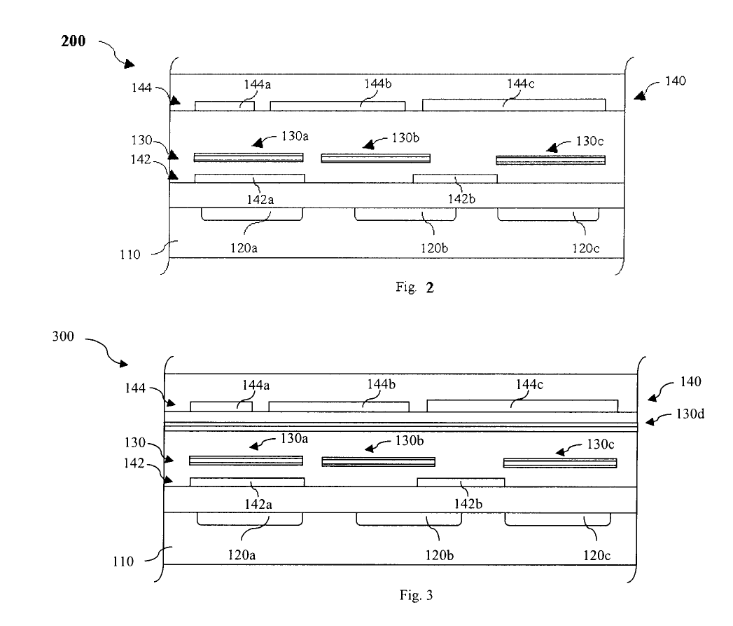

Referring to FIG. 2, illustrated is a sectional view of another embodiment of a semiconductor device 200 having a plurality of backside illuminated sensors constructed according to aspects of the present disclosure. The device 200 may comprise a semiconductor substrate 110, a plurality of sensor elements 120 such as exemplary sensor elements 120a, 120b, and 120c, and other proper components such as color filters and microlens substantially similar to those of the device 100 in terms of configuration, composition, and formation.

The device 200 includes a multilayer interconnect (MLI or interconnect) 140 and a light reflective layer (LRL) 130 integrated and formed together. MLI 140 may comprise at least one interconnect layer. For example, FIG. 2 illustrates a MLI 140 having two exemplary metal layers such as Metal 1 layer 142 and Metal 2 layer 144. The Metal 1 layer 142 may comprise exemplary metal line features 142a and 142b. The Metal 2 layer 144 may comprise exemplary metal line features 144a, 144b, and a dummy metal feature 144c. The MLI 140 may further comprise vertical contacts (not shown) disposed and configured to connect between the metal layer 142 and the semiconductor substrate 110. The MLI 140 may further comprise vertical vias (not shown) disposed and configured to connect between different metal layers such as Metal layer 142 and Metal layer 144. In addition to normal electrical function, the MLI 140 is thus designed and configured to function, at least partially, as the light reflective layer 130. For example, interconnect 142a may be positioned and/or widened to effectively reflect the back-illuminated light to the associated sensor element 120a. In another example, the MLI 140 may comprise multiple metal features (from same layer or different layers), such as exemplary metal features 142b and 144b, configured such that the combined structure (142b and 144b in the example) can effectively reflect the back-illuminated light to the associated sensor element 120b. In another example, the MLI 140 may comprise dummy features such as the dummy metal 144c configured such that by itself or by combination with other features (142b in this example) to effectively reflect the back-illuminated light to the associated sensor element 120c. In another example, contact/via features may additionally be used for the reflection or may be combined with other features for the reflection. All reflective features are preferably designed closer to the light-sensing regions for efficient reflection.

The MLI 140 may comprise conventional interconnects and may be formed by a conventional process well know in the art. In one example, the interconnect 140 may utilize an aluminum technology. In another example, the interconnect 140 may utilize a copper technology. The aluminum interconnect may comprise aluminum, aluminum/silicon/copper alloy, titanium, titanium nitride, tungsten, metal silicide, or combinations. The aluminum interconnect may comprise a multi-film structure. For example, a metal line may comprise barrier/adhesion films having materials such as titanium/titanium nitride and an aluminum film having aluminum alloy. A contact/via feature may comprise similar barrier/adhesion films and a tungsten plug. Aluminum interconnects may be deposited by sputtering, CVD, or combinations thereof. Other manufacturing processes, such as photolithography and etching, may be used to pattern metal materials for vertical connection (vias and contacts) and horizontal connection (metal lines). The copper interconnect may comprise copper, copper alloy, titanium, titanium nitride, tantalum, tantalum nitride, tungsten, metal silicide, tungsten cobalt phosphorous, or combinations. The copper interconnect may be formed using a dual damascene process such as trench first or via first processes. In the dual damascene process, plating and chemical mechanical polishing (CMP) may be utilized.

LRL 130, integrated with MLI 140, may further comprise other metal materials compatible with neighbor features and with the semiconductor processing. For example, a proper metal material may need to be compatible with a semiconductor process utilized to fabricate the semiconductor device 200. A dielectric material may be disposed in the MLI structure and filled empty spaces between metal features. The dielectric material may be substantially similar to the conventional inter-level dielectric (ILD) in the device 100 in term of composition, configuration, and formation. For example, the dielectric material may comprise silicon oxide such as carbon-doped silicon oxide and fluorine-doped silicon oxide, silicon nitride, silicon oxynitride, low k material, combinations thereof, and/or other suitable materials.

Referring to FIG. 3, illustrated is a sectional view of another embodiment of a semiconductor device 300 having a plurality of backside illuminated sensors constructed according to aspects of the present disclosure. The device 300 may comprise a semiconductor substrate 110, a plurality of sensor elements 120 such as exemplary sensor elements 120a, 120b, and 120c, and other suitable components such as color filters, microlens, and interconnects substantially similar to those of the device 200.

The device 300 may further comprise a dielectric light reflective layer (LRL) 130 disposed in and integrated with the inter-layer dielectric (ILD). The dielectric LRL 130 may have a reflective index less than that of the semiconductor substrate 110 and have a reflective index different from that of a neighbor ILD. The dielectric LRL 130 may comprise a dielectric material such as silicon oxide, silicon nitride, silicon oxynitride, low k material, other suitable dielectric material, or combinations thereof. The dielectric LRL 130 may have a plurality of patterned reflective surfaces such as dielectric reflective features 130a, 130b, and 130c, and/or may have a continuous reflective surface such as 130d. The dielectric LRL 130 may comprise a stacked multi-film structure. The stacked multi-film structure may be designed such that each film may have a proper thickness and reflective index for enhanced reflection. For example, the thicknesses of the stacked multiple films may be tuned such that the reflected light will constructively interfere. The reflective index of each film may be carefully chosen or tuned such that the reflection from the multi-films is maximized.

Other configuration and combination may be adopted for reflection enhancement according to known technologies in the art such as thin film optics. In an example, the dielectric LRL 130 may comprise a sandwiched structure having a first layer of a first dielectric material, a second layer of a second dielectric material, and a third layer of the first dielectric material, such as the reflective features 130a, 130b, and 130c illustrated in FIG. 3. In another example, the dielectric LRL 130 may comprise dual films such as the dielectric reflective layer 130d. The dielectric LRL 130 may be formed by a process such as CVD, PVD, thermal oxidation, ALD, spin on glass, other suitable process, or combinations thereof. Other manufacturing technologies may be utilized such as chemical mechanical polishing (CMP). In one example, CMP process may be tuned for minimized dishing and erosion effects to generate a flat surface. In an alternative example, CMP process may be tuned for a proper dishing effect to generate a curved surface for efficient and focused reflection. The dielectric LRL 130 may be combined with the MLI 140 to provide maximized reflection. In one example, the dielectric LRL feature 130b and metal feature 142b (electrically functional line/contact/via or a dummy metal feature) are combined to provide the reflection to the associated sensor element 120b. In another example, the dielectric LRL feature 130c and another dielectric LRL feature 130d in different vertical levels may be combined to provide an enhanced reflection to the associated sensor element 120c. Other proper combination and configuration may be utilized to improve the reflection according to the present disclosure.

As mentioned before, upon formation of the sensor elements, the light reflective layer, the passivation layer, and other structures on the front surface of the semiconductor substrate, the back surface of the semiconductor substrate 110 may be further processed. For example, the back surface may be thinned such that the illuminated light can effectively reach the light-sensing regions. A process such as CMP and/or etching may be used to reduce the thickness of the semiconductor substrate 110. The back surface of the semiconductor substrate 110 may be further protected by a transparent layer having an enough thickness and mechanical strength to support and further protect the semiconductor substrate 110.

In the disclosed structure and the method to make the same, the illuminated light during applications may not be limited to visual light beam, it can be extended to other optical light such as infrared (IR) and ultraviolet (UV), and other proper radiation beams. Accordingly, the light reflective layer 130 may be properly chosen and designed to effectively reflect the corresponding radiation beam.

Thus, the present disclosure provides a backside illuminated semiconductor device. The device comprises a semiconductor substrate having a front surface and a back surface, a sensor element formed on the front surface of the semiconductor substrate, and a light reflective layer (LRL) disposed over the sensor element, wherein the LRL is configured to reflect light directed towards the back surface and through the sensor element.

In the disclosed device, the LRL may be designed to reflect the light directed through more than 80% area of the sensor element. The LRL may reflect at least about 30% of the light directed to. The LRL may have a thickness ranging between about 50 angstrom and 20 micrometer. The LRL may comprise a material selected from the group consisting of metal, dielectric, and combinations thereof. The metal may be selected form the group consisting of aluminum, copper, tungsten, titanium, titanium nitride, tantalum, tantalum nitride, metal silicide, and combinations thereof. The dielectric may be selected from the group consisting of silicon oxide, silicon nitride, silicon oxynitride, low k material, and combinations thereof. The dielectric may have a reflective index less than that of the semiconductor substrate. The LRL may comprise a multilayer structure. The LRL may be disposed within and fabricated with the multilayer interconnect structure. The LRL may comprise a portion of multilayer interconnect. The sensor element may be selected from the group consisting of complementary metal-oxide-semiconductor (CMOS) image sensor, charge-coupled device sensor, active pixel sensor, passive pixel sensor, and combinations thereof. The sensor element may comprise a light-sensing region disposed below the LRL. The light-sensing region may have a doping concentration ranging between about 10¹⁴ and 10²¹ atoms/cm³. The light-sensing region may have an area ranging between about 10% and 80% of pixel area of the sensor element. The light-sensing region may comprise an N-type doped region and/or a P-type doped region.

The present disclosure also provides a semiconductor device. The device includes a semiconductor substrate having a front surface and a backside surface, a plurality of sensor elements disposed on the front surface, and a plurality of metal reflective features disposed over the plurality of sensor elements and configured to reflect light directed toward the back surface of the semiconductor substrate and through at least 80% of the area of each of the plurality of sensor elements. Each of the plurality of metal reflective features may comprise a material selected from the group consisting of aluminum, copper, tungsten, titanium, titanium nitride, tantalum, tantalum nitride, metal silicide, and combinations thereof. The metal reflective features may be disposed in and formed along with multiplayer interconnect above the front surface of the semiconductor substrate. The metal reflective features may comprise a portion of multilayer interconnect. The metal reflective features may be disposed in more than one layer of the multilayer interconnect.

The present disclosure also provides a semiconductor device. The device includes a semiconductor substrate having a front surface and a back surface, a plurality of sensor elements disposed on the front surface, and a dielectric reflective layer disposed in an interlayer dielectric over the plurality of sensor elements and configured to reflect light directed towards the back surface of the semiconductor substrate and through at least 80% area of each of the plurality of sensor elements. The dielectric reflective layer may comprise a material selected from the group consisting of silicon oxide, silicon nitride, silicon oxynitride, low k material, and combinations thereof. The dielectric reflective layer may comprise a multi-film structure.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A backside illuminated semiconductor device, comprising:
a semiconductor substrate having a front surface and a back surface;
a sensor element formed on the front surface of the semiconductor substrate; and
a light reflective layer (LRL) disposed over the semiconductor substrate, wherein the LRL has a reflective surface to the sensor element, wherein the reflective surface has a surface area substantially at least 80% that of the sensor element.

2. The device of claim 1, wherein the sensor element comprises an active pixel sensor.

3. The device of claim 1, wherein the sensor element comprises a passive pixel sensor.

4. The device of claim 1, wherein the LRL has a reflectivity substantially at least 30% to a backside illuminated light.

5. The device of claim 1, wherein the LRL has a thickness ranging between about 50 angstrom and 20 micrometer.

6. The device of claim 1, wherein the LRL comprises metal.

7. The device of claim 6, wherein the metal comprises aluminum.

8. The device of claim 6, wherein the metal comprises copper.

9. The device of claim 6, wherein the metal comprises tungsten.

10. The device of claim 1, wherein the LRL comprises dielectric.

11. The device of claim 10, wherein the dielectric comprises silicon oxide.

12. The device of claim 10, wherein the dielectric comprises silicon nitride.

13. The device of claim 10, wherein the dielectric comprises silicon oxynitride.

14. The device of claim 10, wherein the dielectric has an extinction coefficient about less than 2.

15. The device of claim 1, wherein the LRL comprises a multilayer structure.

16. A backside illuminated semiconductor device, comprising:
a semiconductor substrate having a front surface and a back surface;
a sensor element formed on the front surface of the semiconductor substrate, wherein the sensor element comprises a light-sensing region; and
a light reflective layer (LRL) disposed over the light-sensing region, wherein the LRL is configured to reflect light back to the light-sensing region.

17. The device of claim 16, wherein the light-sensing region has a doping concentration ranging between about 10¹⁴ and 10²¹ atoms/cm³.

18. The device of claim 16, wherein the light-sensing region has an area ranging between about 10% and 80% of a pixel area of the sensor element.

19. The device of claim 16, wherein the light-sensing region comprises an N-type doped region.

20. The device of claim 16, wherein the light-sensing region comprises a P-type doped region.
